(19) United States
(12) Patent Application Publication
(10) Pub. No.: US 2026/0328295 A1
(43) Pub. Date: Oct. 22, 2026

(54) FLUID DELIVERY SYSTEM AND VALVE FOR SAME

(71) Applicant: Ichor Systems, Inc., Fremont, CA (US)

(72) Inventor: Michael Vogtmann, Templeton, CA (US)

(73) Assignee: Ichor Systems, Inc., Fremont, CA (US)

(21) Appl. No.: 19/646,819

(22) Filed: Apr. 14, 2026

Related U.S. Application Data
(60) Provisional application No. 63/789,798, filed on Apr. 16, 2025.

(51) Int. Cl. F16K 7/16; F16K 37/00; H10P 72/00

(52) U.S. Cl. CPC F16K 7/16; F16K 37/005; H10P 72/0402

(57) ABSTRACT

Systems for processing articles are essential for semiconductor fabrication. These systems employ a variety of apparatuses for controlling flow, the apparatuses frequently incorporating valves. In one implementation, a valve may incorporate a flexure element to enable adjustment of both the valve's coefficient of flow and apply the required force to seal a closure element from the ambient environment. The flexure element may be elastically deformable to enable adjustment of a position of the actuator relative to a base of the valve while simultaneously transferring force to the closure member.

### CROSS-REFERENCE TO RELATED APPLICATIONS

This application claims the benefit of U.S. Provisional Application 63/789,798, filed Apr. 16, 2025, which is incorporated herein by reference in its entirety.

### BACKGROUND OF THE INVENTION

Fluid flow control has been one of the key technologies used in semiconductor chip fabrication. Apparatuses for controlling fluid flow are important for delivering process gases and liquids for semiconductor fabrication and other industrial processes. Such devices are used to measure and accurately control the flow of fluids for a variety of applications. In a given fabrication tool, processing systems of the fabrication tool incorporates a variety of apparatuses for controlling flow to deliver a variety of liquids and gases, many of these apparatuses for controlling flow incorporating valves. As a result, efficient gas and liquid handling valves are essential to modern semiconductor fabrication equipment.

As the technology of chip fabrication has improved, so has the demand on the apparatuses for controlling flow. Semiconductor fabrication processes increasingly require increased performance, a greater range of flow capability, more process gases and liquids, and more compact installation of the necessary equipment. Improved apparatuses handling a variety of fluids are desirable, particularly apparatuses providing enhanced reliability, packaging, and reduced cost.

### SUMMARY OF THE INVENTION

The present technology is directed to systems for processing articles such as semiconductors. In other embodiments, the present technology is directed to apparatuses for controlling flows of process fluids. In yet other embodiments, the present technology is directed to valves which may be used in the aforementioned systems and apparatuses. The present systems, apparatuses, and valves may be used in a wide range of processes such as semiconductor chip fabrication, solar panel fabrication, etc.

In one implementation, the invention is a system for processing articles. The system has a fluid supply, an apparatus for controlling flow fluidly coupled to the fluid supply, and a processing chamber fluidly coupled to an outlet of the apparatus for controlling flow. The processing chamber is configured to process semiconductor devices. The apparatus for controlling flow has a body and a valve. The body has a flow path that extends from an inlet to an outlet. The valve is operably coupled to the flow path between the inlet and the outlet. The valve has a first passage extending from a first port, a seat surrounding the first passage, a closure member configured to engage the seat, a second passage extending from the seat to a second port, an actuator configured to move the closure member, and a flexure element compressed between the closure member and the actuator.

In another implementation, the invention is an apparatus for controlling flow. The apparatus for controlling flow has a body and a valve. The body has a flow path extending from an inlet to an outlet. The valve body is operably coupled to the flow path between the inlet and the outlet. The valve has a base, a seat, a closure member, a flexure element, and an actuator. The base has a first passage extending from a first port and a second passage extending from a second port. The first and second passages terminate within a cavity formed in the base. The seat is positioned within the cavity of the base and surrounds an opening of the first passage. The closure member is positioned within the cavity and configured to engage the seat. The flexure element engages the closure member. The actuator engages the flexure element, the actuator configured to selectively move the closure member into and out of contact with the seat.

In yet another implementation, the invention is a valve. The valve has a base, a seat, a closure member, a flexure element, and an actuator. The base has a first passage extending from a first port and a second passage extending from a second port. The first and second passages terminate within a cavity formed in the base. The seat is positioned within the cavity of the base and surrounds an opening of the first passage. The closure member is positioned within the cavity and configured to engage the seat. The closure member is positioned within the cavity and configured to engage the seat. The flexure element seals the closure member within the cavity to isolate the first and second passages from an ambient environment. The actuator engages the flexure element, the actuator configured to selectively move the closure member into and out of contact with the seat.

Further areas of applicability of the present technology will become apparent from the detailed description provided hereinafter. It should be understood that the detailed description and specific examples, while indicating the preferred implementation, are intended for purposes of illustration only and are not intended to limit the scope of the technology.

### BRIEF DESCRIPTION OF THE DRAWINGS

The invention of the present disclosure will become more fully understood from the detailed description and the accompanying drawings, wherein:

FIG. 1 is a schematic of a processing system for manufacturing semiconductor devices utilizing one or more apparatuses for controlling flow.

FIG. 2 is a perspective view of an apparatus for controlling flow as may be utilized in the system of FIG. 1.

FIG. 3 is a perspective view of a valve as may be utilized in the apparatus of FIG. 2.

FIG. 4 is an exploded view of the valve.

FIG. 5 is a left view of the valve.

FIG. 6 is a right view of the valve.

FIG. 7 is a front view of the valve.

FIG. 8 is a rear view of the valve.

FIG. 9 is a top view of the valve.

FIG. 10 is a bottom view of the valve.

FIG. 11 is a cross-sectional view of the valve taken along line 11-11 of FIG. 6.

FIG. 12 is a perspective view of a flexure element as may be used in the valve of FIGS. 3-11.

FIG. 13 is a front view of the flexure element.

FIG. 14 is a cross-sectional view of the flexure element taken along line 14-14 of FIG. 13.

FIG. 15 is a top view of the flexure element.

FIG. 16 is a bottom view of flexure element.

### DETAILED DESCRIPTION

The description of illustrative embodiments according to principles of the present invention is intended to be read in connection with the accompanying drawings, which are to be considered part of the entire written description. In the description of embodiments of the invention disclosed herein, any reference to direction or orientation is merely intended for convenience of description and is not intended in any way to limit the scope of the present invention. Relative terms such as “lower,” “upper,” “horizontal,” “vertical,” “above,” “below,” “up,” “down,” “left,” “right,” “top” and “bottom” as well as derivatives thereof (e.g., “horizontally,” “downwardly,” “upwardly,” etc.) should be construed to refer to the orientation as then described or as shown in the drawing under discussion. These relative terms are for convenience of description only and do not require that the apparatus be constructed or operated in a particular orientation unless explicitly indicated as such. Terms such as “attached,” “affixed,” “connected,” “coupled,” “interconnected,” and similar refer to a relationship wherein structures are secured or attached to one another either directly or indirectly through intervening structures, as well as both movable or rigid attachments or relationships, unless expressly described otherwise. Moreover, the features and benefits of the invention are illustrated by reference to the preferred embodiments. Accordingly, the invention expressly should not be limited to such preferred embodiments illustrating some possible non-limiting combinations of features that may exist alone or in other combinations of features; the scope of the invention being defined by the claims appended hereto.

The present invention is directed to systems for processing articles, these systems having apparatuses for controlling fluid flow which utilize valves. In some embodiments, the apparatuses may function as mass flow controllers to deliver a known mass flow of gas or liquid to a semiconductor or similar process. Semiconductor fabrication is one industry which demands high performance in control of fluid flows. As semiconductor fabrication techniques have advanced, customers have recognized the need for valves with increased accuracy and repeatability in the mass of the delivered fluid flows. Such valves require improved accuracy in flow delivery, reduced cost of manufacture, and greater functionality. The present systems enable improved systems for processing articles by utilizing improved valves and apparatuses incorporating said valves.

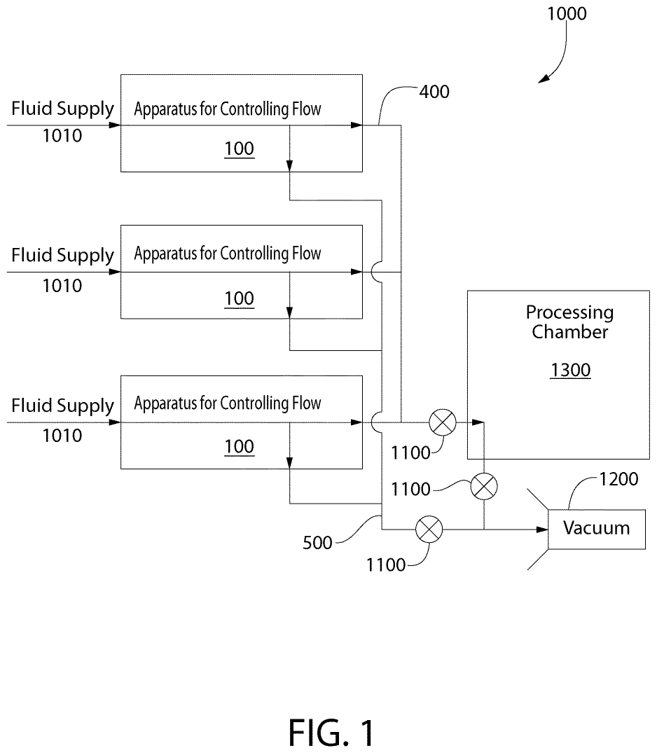

FIG. 1 shows a schematic of an exemplary processing system 1000 for processing articles. The processing system 1000 may utilize a plurality of apparatus for controlling flow 100 fluidly coupled to a processing chamber 1300. Each of the plurality of apparatus for controlling flow 100 has a fluid supply 1010 fluidly coupled thereto, each of the fluid supplies 1010 supplying a process fluid to their respective apparatuses for controlling flow 100. Optionally, a plurality of fluid supplies 1010 may be fluidly coupled to a single apparatus for controlling flow 100 or a plurality of apparatuses for controlling flow 100 may be fluidly coupled to a single fluid supply 1010. Each of the fluid supplies 1010 may deliver a different process fluid or a portion of the fluid supplies 1010 may deliver a single process fluid.

The plurality of apparatus for controlling flow 100 are used to supply one or more different process fluids to the processing chamber 1300 via an outlet manifold 400. Articles such as semiconductors may be processed within the processing chamber 1300. A valve 1100 isolates the apparatuses for controlling flow 100 from the processing chamber 1300, enabling the apparatuses for controlling flow 100 to be selectively connected or isolated from the processing chamber 1300. The processing chamber 1300 may contain one or more applicators to apply process fluids delivered by the plurality of apparatus for controlling flow 100, enabling selective or diffuse distribution of the fluid supplied by the plurality of apparatus for controlling flow 100.

In addition, the processing system 1000 may further comprise a vacuum source 1200 which is isolated from the processing chamber 1300 by a valve 1100 to enable evacuation of process fluids or facilitate purging one or more of the apparatus for controlling flow 100 to enable switching between process fluids in the same apparatus for controlling flow 100. Each of the apparatuses for controlling flow 100 may have a separate bleed port which is coupled to a vent manifold 500, the vent manifold 500 connected to the vacuum source 1200 via a valve 1100. Optionally, the apparatuses for controlling flow 100 may be mass flow controllers, flow splitters, or any other device which controls the flow of a process fluid in a processing system. Furthermore, valves 1100 may be integrated into the apparatus for controlling flow 100 if so desired. In some implementations this may eliminate the need for certain other valves 1100 in the processing system 1000.

Processes that may be performed in the processing system 1000 may include wet cleaning, photolithography, ion implantation, dry etching, atomic layer etching, wet etching, plasma ashing, rapid thermal annealing, furnace annealing, thermal oxidation, chemical vapor deposition, atomic layer deposition, physical vapor deposition, molecular beam epitaxy, laser lift-off, electrochemical deposition, chemical-mechanical polishing, wafer testing, or any other process utilizing controlled volumes of a process fluid.

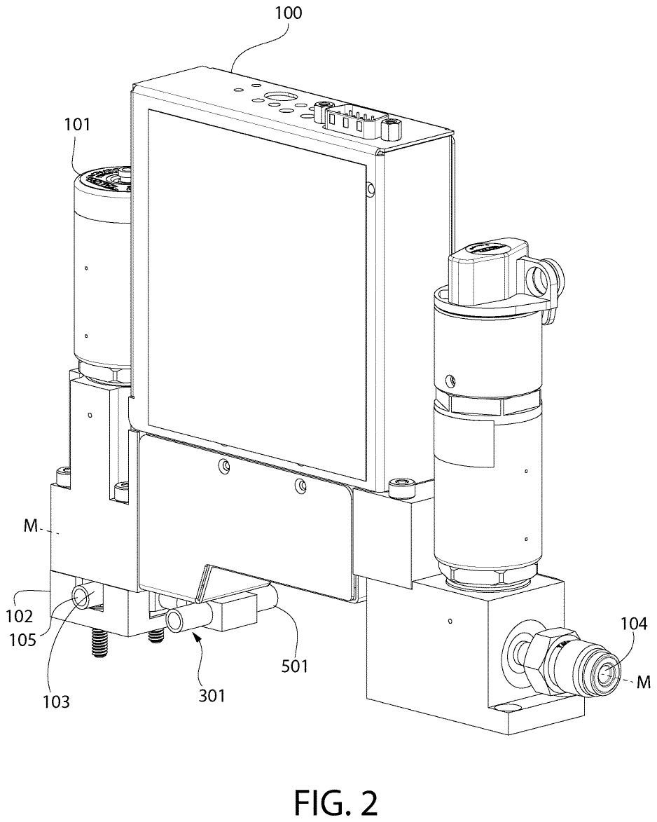

FIG. 2 illustrates an apparatus for controlling flow 100 as may be used in the processing system 1000. The apparatus 100 incorporates a valve 101 mounted to a body 102. A flow path 103 extends from an inlet 104 to an outlet 105. The valve 101 forms a part of the flow path 103, with the valve 101 being capable of slowing or stopping flow of a fluid through the flow path 103 of the apparatus 100.

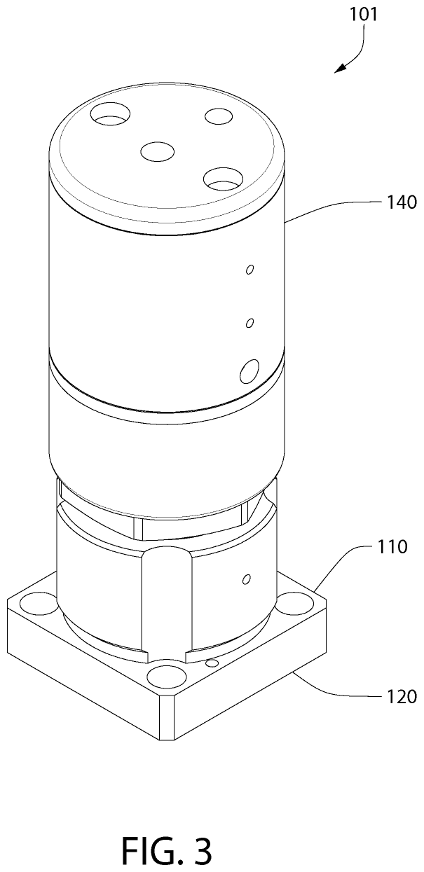

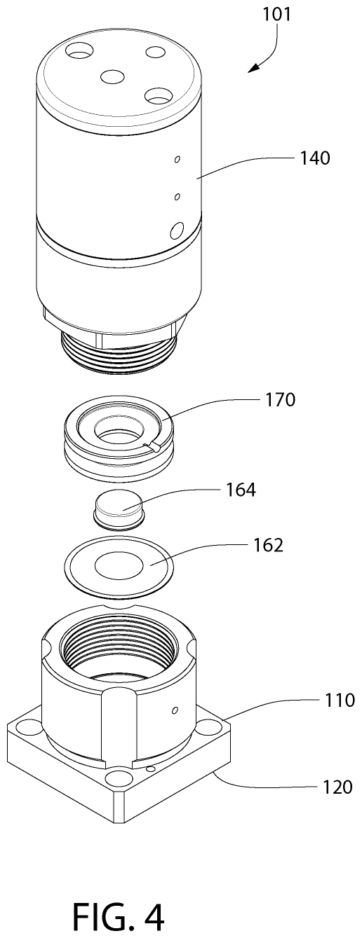

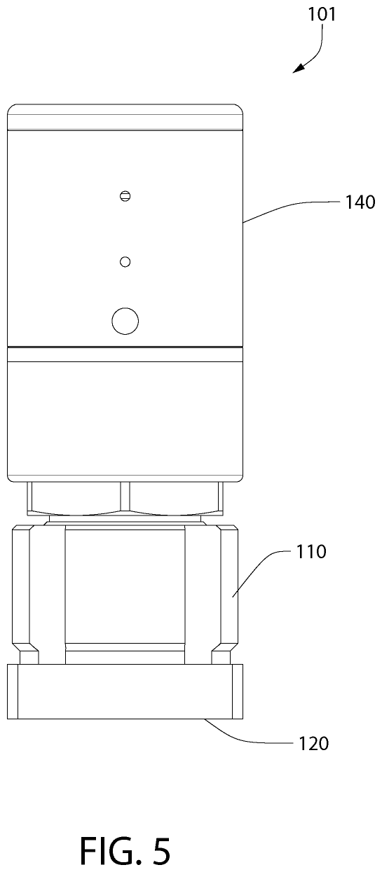

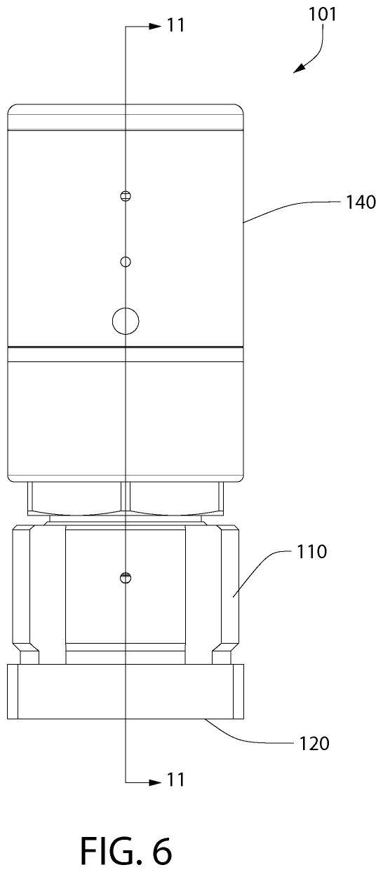

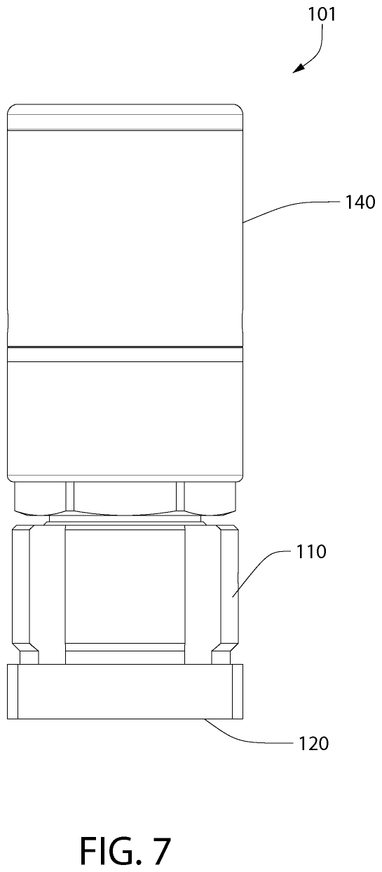

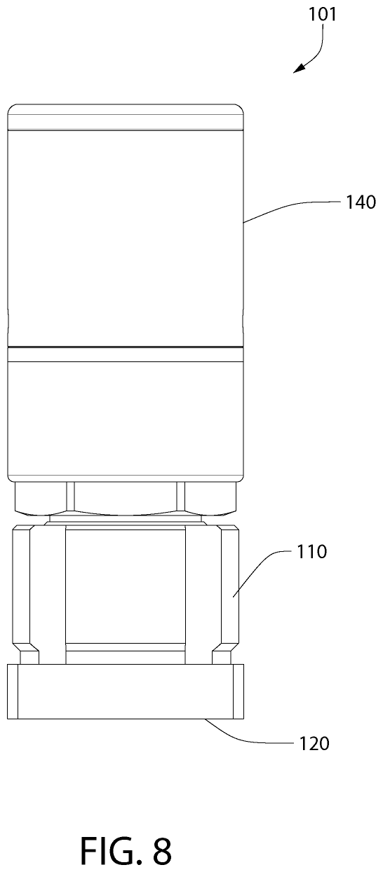

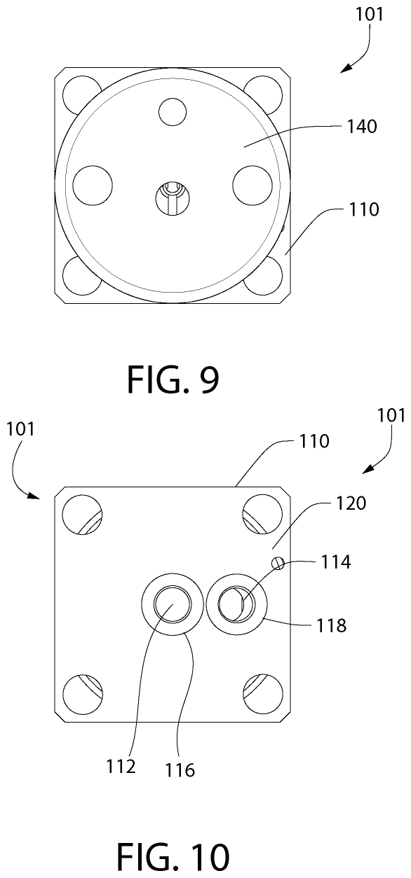

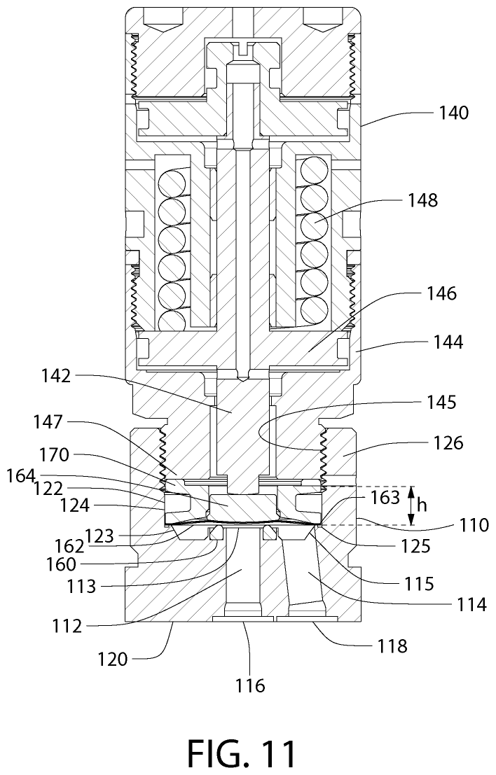

FIGS. 3-10 show a valve 101 as may be used in one or more of the apparatuses for controlling flow 100 that may be utilized in the processing system 1000. The valve 101 has a base 110 and an actuator 140. The actuator 140 may be a pneumatic actuator, an electro-neumatic actuator, a piezoelectric actuator, or any other type of known actuator suitable for actuating the valve. The base 110 comprises first and second passages 112, 114 extending from first and second ports 116, 118 formed in a mounting surface 120 of the base 110.

The first and second passages 112, 114 extend from the mounting surface 120 to a cavity 122 formed in the base 110. The first and second passages 112, 114 each have openings 113, 115 in the cavity 122. The cavity 122 preferably has a floor 123, the openings 113, 115 formed into the floor 123 of the cavity 122. However, in other implementations, the openings 113, 115 may be formed into a wall 124 of the cavity 122. The wall 124 may preferably incorporate threads 126 to receive threads formed on a corresponding portion of the actuator 140.

A seat 160 surrounds the opening 113 of the first passage 112, the seat 160 configured to engage a closure member 162. The closure member 162 may be a diaphragm or other element which is configured to obstruct fluid flow through the valve 101 when the closure member 162 is in contact with the seat 160. The actuator 140 controls a position of the closure member 162 relative to the seat 160 via a button 164 which engages the closure member 162 to ensure even force distribution and improve the sealing action of the closure member 162 against the seat 160.

The button 164 is operated on by a stem 142 of the actuator 140, the stem 142 sliding within a housing 144. Optionally the stem 142 is integrally formed with a piston 146 or other component of the actuator 140. However, in other implementations, the stem 142 may be a separate component. A biasing element 148 biases the valve 101 into a closed state, and the actuator 140 must be activated to move the valve 101 into an open state where the closure member 162 is no longer in contact with the seat 160. The actuator 140 applies a force against the biasing element 148 to open the valve 101. The valve 101 may be operated as a proportional valve capable of partial opening or may be operated as an on/off valve without the capability of partial opening, only moving from fully closed to fully open.

A flexure element 170 is compressed between a peripheral portion 163 of the closure member 162 and the housing 144 of the actuator 140. The flexure element 170 seals the closure member 162 against the floor 123 of the cavity 122 or another element within the cavity 122. The floor 123 may incorporate a sealing ridge 125 or a separate retainer element may be used to retain the seat 160 and also seal the closure member 162 within the cavity 122. The force transmitted by the flexure element 170 to the closure member 162 seals the ambient environment from the first and second passages 112, 114. Thus a flow path 103 extending through the body 102 of an apparatus 100 is isolated from the ambient environment by the closure member 162, the closure member 162 sealed against either the floor 123 of the cavity 122 or a retainer element within the cavity 122.

The flexure element 170 is compressed by a bearing surface 147 of the housing 144 of the actuator 140. The housing 144 has threads 145 which engage the threads 126 formed into the wall 124 of the base 110. The actuator 140 is prevented from rotation by friction between the threads 145, 126 caused by compression of the flexure element 170 against the closure member 162. Thus, the flexure element 170 serves as an anti-rotation device for the threads 145 of the actuator 140.

The deflection of the flexure element 170 further allows setting of a maximum opening position of the closure member 162 with respect to the seat 160. By turning the actuator 140 to increase the compression force applied to the flexure element 170, the maximum opening position is decreased. By turning the actuator 140 to decrease the compression force applied to the flexure element 170, the maximum opening position may be increased. As a result, the valve flow coefficient (“Cv”) of the valve 101 may decrease or increase as measured when the valve 101 is in the fully open state. This is achieved because a height h of the flexure element 170 changes as the actuator 140 is adjusted, with the height h decreasing with increasing force.

Preferably the flexure element 170 is made of metal such as stainless steel, titanium, or a nickel-iron alloy. Specific stainless-steel alloys may include 304, 316, 17-4, 416, or any other known stainless-steel alloy. Exemplary titanium alloys may include 6AL4V or other known titanium alloys. Nickel-iron alloys may include Invar-36 or other known nickel-iron alloys. In a finite element analysis using the exemplary flexure element 170 made of stainless steel, a compression force of 500 lb resulted in a decrease in height h of 0.0023 inches from an uncompressed state. A compression force of 1000 lb resulted in a decrease in height h of 0.0046 inches from the uncompressed state. A compression force of 2000 lb resulted in a decrease in height h of 0.0093 inches from the uncompressed state. A compression force of 3000 lb resulted in a decrease in height h of 0.0139 inches from the uncompressed state. A compression force of 4000 lb resulted in a decrease in height h of 0.0186 inches from the uncompressed state.

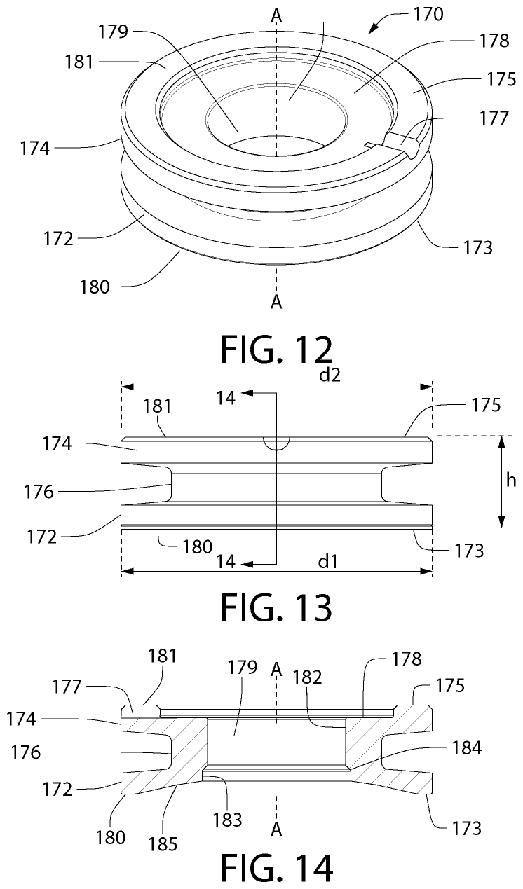

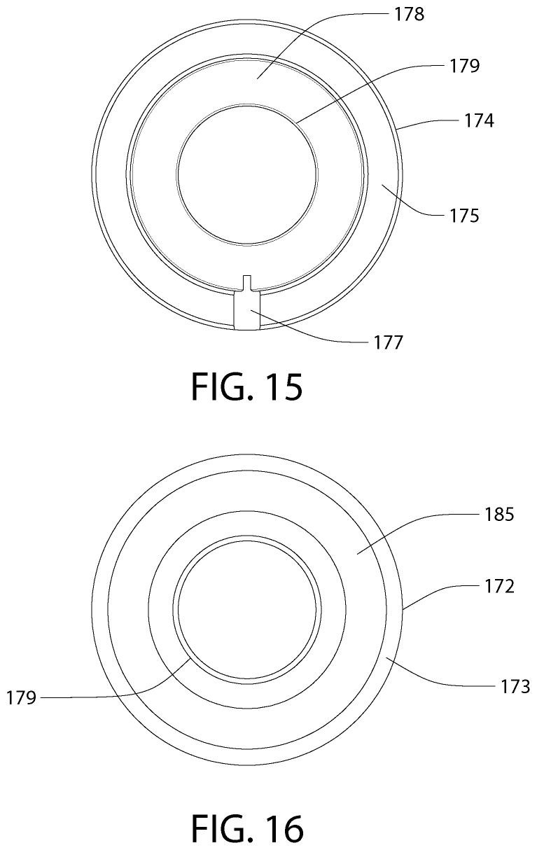

Turning to FIGS. 12-16, the flexure element 170 is shown in greater detail. The flexure element 170 has a first flange 172, a second flange 174, and a central portion 176 extending from the first flange 172 to the second flange 174. The flexure element 170 is substantially symmetric about a longitudinal axis A-A. The first flange 172 has a first diameter d₁ and the second flange 174 has a second diameter d2, the first and second diameters d₁, d₂ being equal. In other implementations, the first and second diameters d₁, d₂ may be unequal, with one being larger than the other. Each of the first and second flanges 172, 174 are centered about the longitudinal axis A-A.

The first flange 172 has a first contact surface 173 which is configured to engage the peripheral portion 163 of the closure member 162. The first contact surface 173 may be planar or may be formed as required to ensure sealing of the closure member 162 within the cavity 122. Preferably, the first contact surface 173 is radially symmetric and perpendicular to the longitudinal axis A-A. The second flange 174 has a second contact surface 175 is configured to engage the bearing surface 147 of the housing 144 of the actuator 140. The second contact surface 175 may be planar or may be formed as required to transfer force applied by the actuator 140.

The second contact surface 175 may further incorporate a channel 177 which allows equalization of pressure between a recess 178 formed around a central aperture 179 extending through the flexure element from a first side 180 to a second side 181. The recess 178 is formed into the second flange 174 and is one element which allows the designer to control an amount of deflection of the flexure element 170 for a given amount of force.

The central aperture 179 has a first wall portion 182, a second wall portion 183, and a shoulder surface 184 which constrain the button 164 and retain it within the central aperture 179 when the flexure element 170 is assembled into a valve 101. The first and second wall portions 182, 183 guide the button 164 as it moves during opening and closing of the valve 101.

A relieved portion 185 is formed into the first flange 172, ensuring that contact with the closure member 162 is limited to the peripheral portion 163. The relieved portion 185 may also be adjusted to control the amount of constraint applied to the button 164 and control an amount of deflection of the flexure element 170 for a given amount of force. The deflection of the height h may also be controlled by the first and second diameters d₁, d₂ of the first and second flanges 172, 174, the material used for the flexure element 170, the diameter of the central aperture 179, the height h of the flexure element 170, and a diameter of the central portion 176, among other factors.

Preferably, the flexure element 170 is designed to achieve a wide range of deflection to enable adjustment of a Cv of the valve 101 while simultaneously ensuring sealing of the closure member 162 within the cavity 122. The central portion 176 allows deflection of the first and second flanges 172, 174. As can be seen, the first and second flanges 172, 174 extend radially a greater distance than the central portion 176. The first and second flanges 172, 174 are radially cantilevered with respect to the central portion, allowing greater deflection prior to elastic deformation of the flexure element 170.

However, in other implementations, the central portion 176 may be either convoluted (i.e. not generally cylindrical) such that it has a zig-zag profile as shown in cross-section or may have another arrangement that ensures that the first and second flanges 172, 174 can deform without being limited to the exemplary embodiment. In all implementations, each of the first flange 172, second flange 174, and central portion 176 have a cross-sectional area as measured perpendicular to the longitudinal axis A-A. The cross-sectional areas of the first and second flanges 172, 174 are greater than the cross-sectional area of the central portion 176. Thus, the central portion 176 has a lesser area than the first and second flanges 172, 174. This promotes deflection of the first and second flanges 172, 174 as discussed above. In addition, each of the first flange 172, the second flange 174, and the central portion 176 have a radial thickness measured perpendicular to the longitudinal axis A-A. The radial thicknesses of the first and second flanges 172, 174 is greater than the radial thickness of the central portion 176.

Exemplary claim Set

Exemplary claim 1: A system for processing articles comprising: a fluid supply; an apparatus for controlling flow fluidly coupled to the fluid supply, the apparatus for controlling flow comprising: a body comprising a flow path extending from an inlet to an outlet; a valve operably coupled to the flow path between the inlet and the outlet, the valve comprising: a first passage extending from a first port; a seat surrounding the first passage; a closure member configured to engage the seat; a second passage extending from the seat to a second port; an actuator configured to move the closure member; and a flexure element compressed between the closure member and the actuator; and a processing chamber fluidly coupled to the outlet of the apparatus for controlling flow, the processing chamber configured to process semiconductor devices.

Exemplary claim 2: The system of exemplary claim 1 further comprising a flow restrictor having a flow impedance located within the flow path and a pressure sensor configured to measure pressure within a volume between the seat of the valve and the flow restrictor.

Exemplary claim 3: The system of exemplary claim 1 or exemplary claim 2 wherein a position of the actuator may be adjusted to alter a maximum opening position of the closure member.

Exemplary claim 4: The system of any one of exemplary claims 1 to 3 wherein the flexure element deflects from an uncompressed state when the actuator is installed within a base of the valve.

Exemplary claim 5: The system of any one of exemplary claims 1 to 4 wherein adjustment of the actuator relative to a base of the valve alters a valve flow coefficient (“Cv”) of the valve.

Exemplary claim 6: The system of exemplary claim 5 wherein adjustment of the actuator causes a height of the flexure element to change.

Exemplary claim 7: The system of any one of exemplary claims 1 to 6 wherein the flexure element is configured to elastically deform when compressed between the closure member and the actuator.

Exemplary claim 8: The system of any one of exemplary claims 1 to 7 wherein the flexure element comprises a first flange and a second flange, the first flange coupled to the second flange by central portion.

Exemplary claim 9: The system of exemplary claim 8 wherein the first flange has a first contact surface engaging a peripheral portion of the closure member and the second flange has a second contact surface engaging the actuator.

Exemplary claim 10: The system of exemplary claim 9 wherein the first flange comprises a relieved portion spaced and isolated from the closure member.

Exemplary claim 11: The system of any one of exemplary claims 8 to 10 wherein the flexure element has a longitudinal axis and the central portion has a cross-sectional area less than a cross-sectional area of either the first or second flanges, the cross-sectional areas of the central portion, first flange, and second flange perpendicular to the longitudinal axis.

Exemplary claim 12: The system of any one of exemplary claims 8 to 11 wherein the flexure element comprises a central aperture extending through the flexure element from a first side to a second side.

Exemplary claim 13: The system of any one of exemplary claims 1 to 12 wherein the flexure element is formed of a metal material.

Exemplary claim 14: The system of any one of exemplary claims 1 to 13 wherein the flexure element seals the closure member within a cavity of a base of the valve to isolate the flow path from an ambient environment.

Exemplary claim 15: An apparatus for controlling flow comprising: a body comprising a flow path extending from an inlet to an outlet; a valve operably coupled to the flow path between the inlet and the outlet, the valve comprising: a base having a first passage extending from a first port and a second passage extending from a second port, the first and second passages terminating within a cavity formed in the base; a seat positioned within the cavity of the base and surrounding an opening of the first passage; a closure member positioned within the cavity and configured to engage the seat; a flexure element engaging the closure member; and an actuator engaging the flexure element, the actuator configured to selectively move the closure member into and out of contact with the seat.

Exemplary claim 16: The apparatus of exemplary claim 15 further comprising a flow restrictor having a flow impedance located within one of the first and second passages and a pressure sensor configured to measure pressure within a volume between the seat of the valve and the flow restrictor.

Exemplary claim 17: The apparatus of exemplary claim 15 or exemplary claim 16 wherein a position of the actuator may be adjusted to alter a maximum opening position of the closure member.

Exemplary claim 18: The apparatus of any one of exemplary claims 15 to 17 wherein the flexure element deflects from an uncompressed state when the actuator is installed within a base of the valve.

Exemplary claim 19: The apparatus of any one of exemplary claims 15 to 18 wherein adjustment of the actuator relative to a base of the valve alters a valve flow coefficient (“Cv”) of the valve.

Exemplary claim 20: The apparatus of exemplary claim 19 wherein adjustment of the actuator causes a height of the flexure element to change.

Exemplary claim 21: The apparatus of any one of exemplary claims 15 to 20 wherein the flexure element is configured to elastically deform when compressed between the closure member and the actuator.

Exemplary claim 22: The apparatus of any one of exemplary claims 15 to 21 wherein the flexure element comprises a first flange and a second flange, the first flange coupled to the second flange by central portion.

Exemplary claim 23: The apparatus of exemplary claim 22 wherein the first flange has a first contact surface engaging a peripheral portion of the closure member and the second flange has a second contact surface engaging the actuator.

Exemplary claim 24: The apparatus of exemplary claim 23 wherein the first flange comprises a relieved portion spaced and isolated from the closure member.

Exemplary claim 25: The apparatus of any one of exemplary claims 22 to 24 wherein the flexure element has a longitudinal axis and the central portion has a cross-sectional area less than a cross-sectional area of either the first or second flanges, the cross-sectional areas of the central portion, first flange, and second flange perpendicular to the longitudinal axis.

Exemplary claim 26: The apparatus of any one of exemplary claims 22 to 25 wherein the flexure element comprises a central aperture extending through the flexure element from a first side to a second side.

Exemplary claim 27: The apparatus of any one of exemplary claims 15 to 26 wherein the flexure element is formed of a metal material.

Exemplary claim 28: The apparatus of any one of exemplary claims 15 to 27 wherein the flexure element seals the closure member within a cavity of the base of the valve to isolate the first and second passages from an ambient environment.

Exemplary claim 29: A valve comprising: a base comprising a first passage extending from a first port and a second passage extending from a second port, the first and second passages terminating within a cavity formed in the base; a seat positioned within the cavity of the base and surrounding an opening of the first passage; a closure member positioned within the cavity and configured to engage the seat; a flexure element sealing the closure member within the cavity to isolate the first and second passages from an ambient environment; and an actuator engaging the flexure element, the actuator configured to selectively move the closure member into and out of contact with the seat.

Exemplary claim 30: The valve of exemplary claim 29 further comprising a flow restrictor having a flow impedance located within one of the first and second passages and a pressure sensor configured to measure pressure within a volume between the seat of the valve and the flow restrictor.

Exemplary claim 31: The valve of exemplary claim 29 or exemplary claim 30 wherein a position of the actuator may be adjusted to alter a maximum opening position of the closure member.

Exemplary claim 32: The valve of any one of exemplary claims 29 to 31 wherein the flexure element deflects from an uncompressed state when the actuator is installed within a base of the valve.

Exemplary claim 33: The valve of any one of exemplary claims 29 to 32 wherein adjustment of the actuator relative to a base of the valve alters a valve flow coefficient (“Cv”) of the valve.

Exemplary claim 34: The valve of exemplary claim 33 wherein adjustment of the actuator causes a height of the flexure element to change.

Exemplary claim 35: The valve of any one of exemplary claims 29 to 34 wherein the flexure element is configured to elastically deform when compressed between the closure member and the actuator.

Exemplary claim 36: The valve of any one of exemplary claims 29 to 35 wherein the flexure element comprises a first flange and a second flange, the first flange coupled to the second flange by central portion.

Exemplary claim 37: The valve of exemplary claim 36 wherein the first flange has a first contact surface engaging a peripheral portion of the closure member and the second flange has a second contact surface engaging the actuator.

Exemplary claim 38: The valve of exemplary claim 37 wherein the first flange comprises a relieved portion spaced and isolated from the closure member.

Exemplary claim 39: The valve of any one of exemplary claims 36 to 38 wherein the flexure element has a longitudinal axis and the central portion has a cross-sectional area less than a cross-sectional area of either the first or second flanges, the cross-sectional areas of the central portion, first flange, and second flange perpendicular to the longitudinal axis.

Exemplary claim 40: The valve of any one of exemplary claims 36 to 39 wherein the flexure element comprises a central aperture extending through the flexure element from a first side to a second side.

Exemplary claim 41: The valve of any one of exemplary claims 29 to 40 wherein the flexure element is formed of a metal material.

Exemplary claim 42: The valve of any one of exemplary claims 29 to 41 wherein the flexure element is compressed between the closure member and the actuator.

While the invention has been described with respect to specific examples including presently preferred modes of carrying out the invention, those skilled in the art will appreciate that there are numerous variations and permutations of the above described systems and techniques. It is to be understood that other embodiments may be utilized, and structural and functional modifications may be made without departing from the scope of the present invention. Thus, the spirit and scope of the invention should be construed broadly as set forth in the appended claims.

1. A system for processing articles comprising:
a fluid supply;
an apparatus for controlling flow fluidly coupled to the fluid supply, the apparatus for controlling flow comprising:
a body comprising a flow path extending from an inlet to an outlet;
a valve operably coupled to the flow path between the inlet and the outlet, the valve comprising:
a first passage extending from a first port;
a seat surrounding the first passage;
a closure member configured to engage the seat;
a second passage extending from the seat to a second port;
an actuator configured to move the closure member; and
a flexure element compressed between the closure member and the actuator; and
a processing chamber fluidly coupled to the outlet of the apparatus for controlling flow, the processing chamber configured to process semiconductor devices.

2. The system of claim 1 further comprising a flow restrictor having a flow impedance located within the flow path and a pressure sensor configured to measure pressure within a volume between the seat of the valve and the flow restrictor.

3. The system of claim 1 wherein a position of the actuator may be adjusted to alter a maximum opening position of the closure member.

4. The system of claim 1 wherein the flexure element deflects from an uncompressed state when the actuator is installed within a base of the valve.

5. The system of claim 1 wherein adjustment of the actuator relative to a base of the valve alters a valve flow coefficient (“Cv”) of the valve.

6. The system of claim 5 wherein adjustment of the actuator causes a height of the flexure element to change.

7. The system of claim 1 wherein the flexure element is configured to elastically deform when compressed between the closure member and the actuator.

8. The system of claim 1 wherein the flexure element comprises a first flange and a second flange, the first flange coupled to the second flange by central portion.

9. The system of claim 8 wherein the first flange has a first contact surface engaging a peripheral portion of the closure member and the second flange has a second contact surface engaging the actuator.

10. The system of claim 9 wherein the first flange comprises a relieved portion spaced and isolated from the closure member.

11. The system of claim 8 wherein the flexure element has a longitudinal axis and the central portion has a cross-sectional area less than a cross-sectional area of either the first or second flanges, the cross-sectional areas of the central portion, first flange, and second flange perpendicular to the longitudinal axis.

12. The system of claim 8 wherein the flexure element comprises a central aperture extending through the flexure element from a first side to a second side.

13. (canceled)

14. (canceled)

15. An apparatus for controlling flow comprising:
a body comprising a flow path extending from an inlet to an outlet;
a valve operably coupled to the flow path between the inlet and the outlet, the valve comprising:
a base having a first passage extending from a first port and a second passage extending from a second port, the first and second passages terminating within a cavity formed in the base;
a seat positioned within the cavity of the base and surrounding an opening of the first passage;
a closure member positioned within the cavity and configured to engage the seat;
a flexure element engaging the closure member; and
an actuator engaging the flexure element, the actuator configured to selectively move the closure member into and out of contact with the seat.

16. (canceled)

17. (canceled)

18. The apparatus of claim 15 wherein the flexure element deflects from an uncompressed state when the actuator is installed within a base of the valve.

19. The apparatus of claim 15 wherein adjustment of the actuator relative to a base of the valve alters a valve flow coefficient (“Cv”) of the valve.

20. The apparatus of claim 19 wherein adjustment of the actuator causes a height of the flexure element to change.

21. The apparatus of claim 15 wherein the flexure element is configured to elastically deform when compressed between the closure member and the actuator.

22.-28. (canceled)

29. A valve comprising:
a base comprising a first passage extending from a first port and a second passage extending from a second port, the first and second passages terminating within a cavity formed in the base;
a seat positioned within the cavity of the base and surrounding an opening of the first passage;
a closure member positioned within the cavity and configured to engage the seat;
a flexure element sealing the closure member within the cavity to isolate the first and second passages from an ambient environment; and
an actuator engaging the flexure element, the actuator configured to selectively move the closure member into and out of contact with the seat.

30.-32. (canceled)

33. The valve of claim 29 wherein adjustment of the actuator relative to a base of the valve alters a valve flow coefficient (“Cv”) of the valve.

34. The valve of claim 33 wherein adjustment of the actuator causes a height of the flexure element to change.

35.-42. (canceled)
